(19) United States
(12) Patent Application Publication
(10) Pub. No.: US 2009/0165839 A1
(43) Pub. Date: Jul. 2, 2009

(54) Photovoltaic Cell

(76) Inventors: Miroslav Zeman, Delft (NL); Gert Jan Jongerden, Velp (NL)

Correspondence Address: OLIFF & BERRIDGE, PLC, P.O. BOX 320850, ALEXANDRIA, VA, 22320-4850, US

(21) Appl. No.: 12/085,580

(22) PCT Filed: Nov. 30, 2006
(86) PCT No.: PCT/EP2006/069140

§ 371 Date: Aug. 4, 2008

Related U.S. Application Data
(60) Provisional application No. 60/763,916, filed on Feb. 1, 2006.

(30) Foreign Application Priority Data
Dec. 2, 2005 (EP) 05111611.9

(51) Int. Cl. H01L 31/042; H01L 31/00; H01L 31/18

(52) U.S. Cl. 136/244; 136/256; 136/255; 438/73; 257/E21.158

(57) ABSTRACT

The invention relates to a photovoltaic cell, including at least a first junction between a pair of semiconducting regions (4-9). At least one of the pair of semiconducting regions includes at least part of a superlattice comprising a first material interspersed with formations of a second material. The formations are of sufficiently small dimensions so that the effective band gap of the superlattice is at least partly determined by the dimensions. An absorption layer (24-26) is provided between the semiconducting regions and the absorption layer comprises a material for absorption of radiation so as to result in excitation of charge carriers and is of such thickness that excitation levels are determined by the material itself. At least one of the effective energy bands of the superlattice and one of the excitation levels of the material of the absorption layer is selected to match at least one of the excitation levels of the material of the absorption layer and the effective energy band of the superlattice, respectively.

The invention relates to a photovoltaic cell, including at least a first junction between a pair of semiconducting regions, wherein at least one of the pair of semiconducting regions includes at least part of a superlattice comprising a first material interspersed with formations of a second material, which formations are of sufficiently small dimensions that the effective band gap of the superlattice is at least partly determined by the dimensions, wherein an absorption layer is provided between the semiconducting regions and wherein the absorption layer comprises a material for absorption of radiation so as to result in excitation of charge carriers and is of such thickness that excitation levels are determined by the material itself.

The invention also relates to a method of manufacturing an array of photovoltaic cells.

The invention also relates to a photovoltaic device including a plurality of photovoltaic cells.

Examples of such a photovoltaic cell, method and photovoltaic device are known. U.S. Pat. No. 4,718,947 describes a p-i-n photovoltaic cell comprising a transparent substrate made of glass or plastic and coated with a layer of transparent conductive oxide. A p-layer is formed on the conductive oxide layer, and an intrinsic layer (i-layer) is formed on the p-layer. An n-layer is formed on the i-layer and a metal back contact layer is formed on the n-layer. Superlattices are used to form the p-layer and/or n-layer in order to lower the absorption in the doped layers without decreasing their conductivity.

U.S. Pat. No. 4,598,164 describes a tandem solar cell which includes a first active region including a superlattice material wherein the band gap has a first predetermined value; a second active region including a second superlattice material wherein the band gap has a second predetermined value and a means for electrically interconnecting the first and second active regions such that current may flow between the first and second active regions. The amorphous superlattice is a multilayered material whose layers are thin sheets of semiconducting or insulating tetrahedrally bonded amorphous material, where the material is formed from tetrahedrally bonded elements or alloys containing said tetrahedrally bonded elements. Each layer is less than about 1500 Å thick.

A problem of the latter cell is that, in order to make it sufficiently efficient, it must comprise very many of the combinations of layers of different semiconducting materials that form the active regions. Otherwise, only a small fraction of the incident light will be absorbed in the active region formed by a superlattice. However, adding extra layers to the superlattice will make the known device expensive to manufacture.

It is an object of the invention to provide a photovoltaic cell, method and photovoltaic device that provide relatively efficient conversion of solar energy for a given manufacturing effort.

This object is achieved by means of the photovoltaic cell, which is characterised in that at least one of the effective energy bands of the superlattice and one of the energy excitation levels of the material of the absorption layer is selected to substantially match at least one of the energy excitation level of the material of the absorption layer and the effective energy band of the superlattice, respectively.

Because at least a first of the two semiconducting regions includes at least part of a superlattice, the photovoltaic cell can be made relatively efficient. The effective band gap of the superlattice may be tuned to an advantageous range of the solar spectrum. The disadvantage that the dimensions of the formations of both materials must be sufficiently small to provide the superlattice with an effective band gap differing from that of any semiconductor materials in the individual layers of the superlattice—and that many layers would ordinarily have to be deposited to build a photovoltaic cell absorbing sufficient radiation—is lessened due to the presence of the layer of material for absorption of radiation so as to result in excitation of charge carriers. The excited charge carriers are transferred to the adjoining superlattice, thus enhancing the efficiency of conversion of solar energy.

Within a photovoltaic cell, a distinction can be made between the functions of absorption of radiation to generate excited charge carriers, subsequent separation of charge carriers of opposite polarity (due to the presence of p- and n-type doped layers opposite charges are pulled in a built-in electric field in opposite directions), transport of charge carriers and collection of the separated and transported charge carriers. An advantage of the proposed structure is that a separation of functions is achieved, and can be further optimised. The material of the absorption layer for absorption of radiation can be selected specifically to have a high absorption coefficient, whereas the first and second materials forming the superlattice, as well as the dimensions of the formations of both materials are selected to provide a desired effective band gap. The effective band gap depends on both the chemical and/or structural composition and the dimensions of the formations of materials in the superlattice. The excitation levels of the absorption layer for absorption of radiation, which is homogeneous to allow formation in one process step, are independent of the thickness of the layer. They only depend on its chemical composition and/or the phase of its constituents.

Where the excitation level of the absorption layer for absorption of radiation corresponds substantially to the effective conduction band, transfer of negative charge carriers is more efficient. Less energy is lost upon transfer when the level corresponds, for example, to within 0.2 eV, more preferably less than 0.1 eV, of the lower edge of the effective conduction band. Where the material of the absorption layer for absorption of radiation exhibits at least one stable energy level corresponding substantially to an effective valence band of a semiconducting region adjoining the absorption layer, the transfer of positive charge carriers is more efficient. Less energy is lost upon transfer when the level corresponds, for example, to within 0.2 eV, more preferably less than 0.1 eV, of the upper edge of the effective valence band. In other words, selection of at least one of the effective bands of the superlattice and one of the excitation levels of the material of the absorption layer to substantially match at least one of the excitation level of the material of the absorption layer and the effective band of the superlattice, respectively, increases the efficiency of the photovoltaic cell. The semiconducting region including at least part of the superlattice functions as an energy-selective transport layer, to remove the carriers generated absorption layer for absorption of radiation.

An embodiment comprises a series of pairs of semiconducting regions, separated by junctions and having effective band gaps decreasing with each pair, wherein at least two of the semiconducting regions include a superlattice and an adjoining absorption layer of a material for absorption of radiation so as to result in excitation of charge carriers, of such thickness that excitation levels are determined by the material itself.

Thus, a so-called tandem-cell or multi-junction cell is provided. The advantage of this configuration is that it can be used to convert different ranges of the solar spectrum in different regions, adapted specifically to the respective ranges. This diminishes the thermalisation of charge carriers, i.e. the generation of heat when a charge carrier is created by absorption of a photon having a higher energy than the effective band gap of the region in which it is absorbed. The presence, immediately adjacent the successive superlattices, of an absorption layer of a material for absorption of radiation so as to result in excitation of charge carriers, of such thickness that excitation levels are determined by the material itself, ensures that as much as possible of a frequency range is filtered out before the radiation reaches a next semiconducting region in the series.

In an embodiment, each superlattice comprises a periodically repeating combination of layers of different semiconductor materials, sufficiently thin to provide the superlattice with an effective band gap differing from that of any semiconductor materials in the individual layers of the superlattice.

Compared to alternative embodiments, such as those with a quantum dot superlattice, this embodiment has the advantage that a clear route to manufacturing such superlattices on an industrial scale exists.

In an embodiment, the absorption layer is sandwiched between the semiconducting regions and the semiconducting regions have different effective band gaps.

This embodiment allows that charge carriers generated on both sides of the absorption layer contribute to the efficiency of the photovoltaic cell.

In an embodiment, the material for absorption of radiation comprises at least one of a direct semiconductor, an organic molecular material and a material comprising nano-crystals.

The latter type of material includes materials comprising multiphase structures e.g. consisting of a matrix with nanometer-sized particles regularly positioned in the material. In these materials the absorption edge can be manipulated by changing the size of the particles and can therefore be energetically matched to the effective band gap of the adjacent superlattice. This contributes to making the photovoltaic cell relatively efficient. Organic molecular materials are most readily adaptable to achieve absorption in a particular range of the solar spectrum, as well as being easiest to adapt to match the effective conduction band and/or valence band of a particular superlattice.

In an embodiment, the superlattice comprises a periodically repeating combination of layers of different amorphous semiconductor materials.

The effect is substantially to avoid any stress due to lattice mismatch. For this reason, layers of amorphous semiconductor materials are easiest to stack.

In an embodiment, the superlattice comprises a periodically repeating combination of layers of hydrogenated semiconductor materials.

The effect is to passivate coordination defects.

According to another aspect, the method of manufacturing an array of photovoltaic cells includes depositing layers of material on a length of foil and patterning at least one of the layers to form an array of photovoltaic cells, wherein an array of cells according to the invention is formed.

Due to the configuration of the photovoltaic cells, fewer layers of material need be deposited, resulting in substantial savings in manufacturing effort.

Preferably, layers are deposited at least one station in a production line, wherein a quasi-continuous length of foil is advanced past each station.

This is an advantageous way of manufacturing arrays of photovoltaic cells, since the desired array can be cut off from the foil. Moreover, time-consuming chamber conditioning is avoided and the exchange time between depositions of layers of material is cut out from the total time to manufacture the array.

According to another aspect, the photovoltaic device according to the invention includes a plurality of photovoltaic cells according to the invention.

The device is relatively easy to manufacture, as well as exhibiting good energy conversion efficiency.

The invention will now be described in further detail with reference to the accompanying drawings, in which:

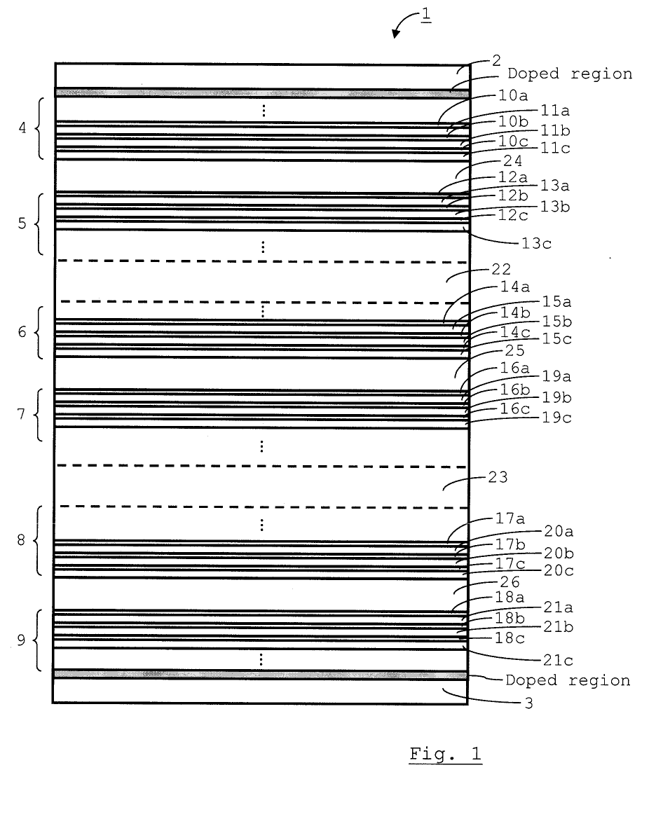

FIG. 1 schematically shows the build-up of an example of a photovoltaic cell, not to scale;

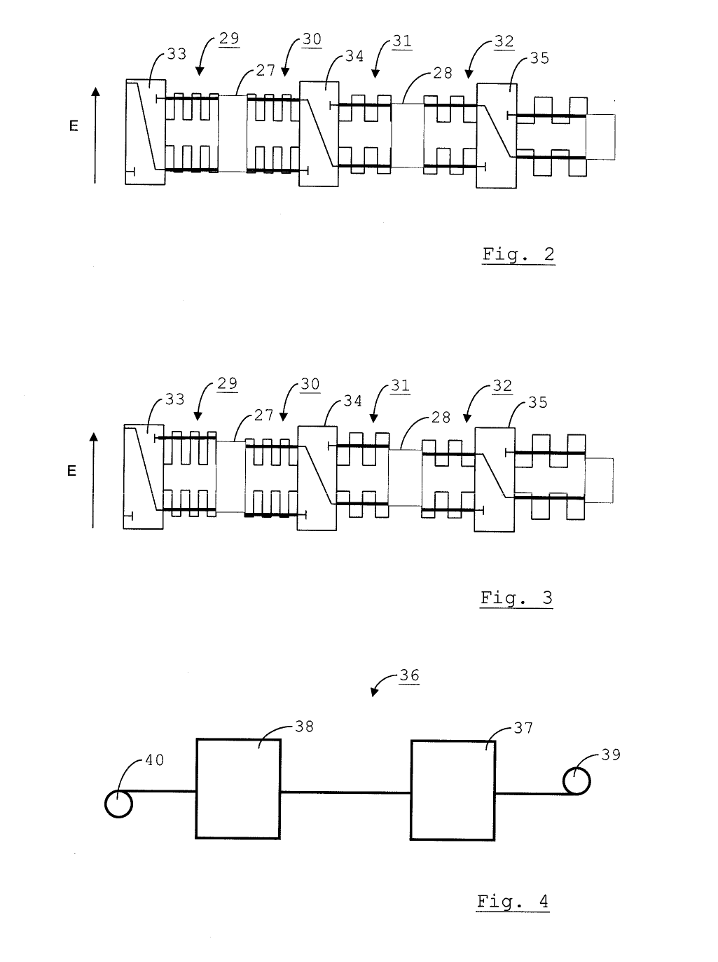

FIG. 2 shows an energy diagram of a variant of the photovoltaic cell;

FIG. 3 shows an energy diagram of another variant of the photovoltaic cell, and

FIG. 4 schematically shows a production line for manufacturing arrays of photovoltaic cells.

A photovoltaic cell 1 is shown in FIG. 1 only insofar as necessary for illustrating the invention. In an actual photovoltaic device, the photovoltaic cell 1 would be encapsulated in further layers, including one or more layers of plastic foil for sealing the photovoltaic cell from the environment and/or sheets of glass. In the illustrated embodiment, the photovoltaic cell 1 is a tandem cell, i.e. a stack of component cells. In this case, the individual cells in the stack are electrically connected in series. Parallel connection is an alternative, but more complicated.

The illustrated photovoltaic cell 1 is a two-terminal device, and includes a top electrode 2 and a back electrode 3. The top electrode is made of a transparent conducting material, for example SnO₂ (tin oxide), ITO (indium tin oxide), ZnO (zinc oxide), Zn₂SnO₄ (zinc stannate), Cd₂SnO₄ (Cadmium stannate) or InTiO (Indium Titanium oxide). The back electrode 3 is at least partly made of a metal, such as Al (aluminium) or Ag (silver), a metal alloy or a transparent conducting material. In an embodiment, the back electrode 3 is made of a combination of a metal and a transparent conducting material, the former being situated towards the outside of the photovoltaic cell 1.

The photovoltaic cell 1 in the embodiment of FIG. 1 comprises semiconducting regions 4-9. In other embodiments, there may be fewer or more of such regions. Of each pair of semiconducting regions, one functions as an efficient transport region for electrons and the other is arranged to function as an efficient transport region for holes.

In the embodiment of FIG. 1, each of the semiconducting regions 4-9 comprises a superlattice. Semiconductors based on superlattices are known in the art. In the present text, the term superlattice will be used to denote both known variants: those comprising layers of a first material interspersed with layers of a second material, both being sufficiently thin to affect the band gap and those wherein nanocrystals are formed from an semiconducting layer, where the size of the nanocrystals, or quantum dots, affect the effective band gap of the superlattice. An example of the latter kind of superlattice is set out more fully in Green, M. A., “Silicon nanostructures for all-silicon tandem solar cells”, 19th European Photovoltaic Solar Energy Conference and Exhibition, Paris, June 7th-11th, 2004. Superlattices of the layered kind are comprised in the embodiment described herein in more detail.

The layered superlattices comprise a periodically repeating combination of a layer of a low band gap semiconductor material, called the well, with a layer of a wide band gap material, called the barrier. Thus, in FIG. 1, a first semiconducting region 4 includes a repeating combination of first barrier layers 10a-10c and first well layers 11a-11c. A second semiconducting region 5 includes a repeating combination of second barrier layers 12a-12c and second well layers 13a-13c, whereas a third semiconducting region 6 includes a repeating combination of third barrier layers 14a-14c and third well layers 15a-15c. Fourth, fifth and sixth semiconducting regions 7-9 include fourth, fifth and sixth barrier layers 16a-16c, 17a-17c and 18a-18c, respectively, alternating with fourth, fifth and sixth well layers 19a-19c, 20a-20c and 21a-21c, respectively. The values of the thickness of the layers 10-21 lie in the range of 1-2 nm, at least below 10 nm. Each of the semiconducting regions 4-9 has a total thickness in the order of a hundred nm, at least below 200 nm.

The layers 10-21 of the present example are made of hydrogenated or fluorinated amorphous semiconducting materials. Suitable examples include hydrogenated amorphous silicon (a-Si:H), hydrogenated amorphous silicon germanium (a-SiGe:H), hydrogenated amorphous silicon carbide (a-SiC:H), hydrogenated amorphous silicon nitride (a-SiN:H) and hydrogenated amorphous silicon oxide (a-SiO:H). The band gap of a-Si:H depends on the deposition conditions and varies from 1.6 eV to 1.9 eV. Alloying a-Si:H with carbon, oxygen or nitrogen widens the band gap of the alloys, whereas incorporating germanium lowers the band gap. Suitable embodiments can be made by using a-Si:H and a-SiGe:H as material for the wells, i.e. the well layers 11,13,15,19,21 and using a-SiC:H, a-SiN:H or a-SiO:H as material for the barriers, i.e. the barrier layers 10,12,14,16,18. The non-periodic structure of a-Si:H based layers and the ability of hydrogen to passivate coordination defects eliminate the stringent requirements for lattice matching that apply to crystalline superlattices.

To form the superlattices, one or more of several techniques may be used. These techniques include chemical vapour deposition, reactive (co-) sputtering, reactive (co-) evaporation, etc. To manufacture the illustrated example, an advantageous technique is Plasma Enhanced Chemical Vapour Deposition (PECVD). This technique is advantageous because the alloying of a-Si:H can be accomplished easily by adding appropriate gases to the silicon carrying source gas such as silane. It has been demonstrated that superlattices can be fabricated that are neither lattice matched nor epitaxial, yet with interfaces that are essentially free of defects and nearly atomically sharp.

The adjacent semiconducting regions 4-9 of different pairs are separated by tunnel-recombination junctions 22,23 that include N-type and P-type regions. The tunnel-recombination junctions 22,23 provide for the internal series connection, where the recombination of oppositely charged carriers arriving from the adjacent pairs of semi-conducting regions takes place. Tunneling of the carriers through the layers forming the tunnel-recombination junction facilitates the recombination. The effective recombination of the photo-generated carriers takes place through the defect states in the centre of the junction. The recombination of the photo-generated carriers in the centre of the junction keeps the current flowing through the solar cell.

Of each pair of semiconducting regions, one is arranged to function as an efficient transport region for holes and the other as an efficient transport region for electrons. In the illustrated embodiment of FIG. 1, the superlattices are attached to an N-type semiconductor region and a P-type semiconductor region, i.e. doped semiconductor regions that form a part of the tunnel recombination junctions 22,23. It is noted that the doped regions may also comprise superlattices.

As is well known, the space charge in the differently doped semiconductors generated due to the out-diffusion of majority charge carriers from the doped layers gives rise to an internal electric field. This brings about a separation of mobile charge carriers created by excitation. The combination of the first and second semiconducting regions 4,5 converts solar energy in a first range of the solar spectrum, the combination of the third and fourth semiconducting regions 6,7 converts a second, different but possibly overlapping region of the solar spectrum, and the combination of the fifth and sixth semiconducting regions 8,9 yet another range. The tunnel recombination junctions 22,23 ensure that the three pairs of semiconducting regions are electrically connected in series.

The semiconducting regions 4-9 have progressively decreasing effective band gaps. Thus, a first and second semiconducting region 4,5 have a larger effective band gap, so as to capture photons in a higher (frequency) range of the solar spectrum. Intermediate semiconducting regions 6,7 have an effective band gap in an intermediate range of the solar spectrum. Lower semiconducting regions 8,9 have an effective band gap in a lower range of the solar spectrum. The top semiconducting regions 4,5 are situated nearest the top electrode 2. The top electrode 2 is exposed to incoming light, in use, which thus passes through the semiconducting regions 4-9 in order of decreasing effective band gap. This configuration provides improved efficiency of solar energy conversion, due to suppression of thermalisation of charge carriers.

As a result of the incorporation of respective first, second and third absorption layers 24-26 of materials for absorption of radiation in between the top, intermediate and lower pairs of semiconducting regions 4-9, absorption of incident radiation is largely accounted for by the absorption layers. Consequently, the thickness of the semiconducting regions can be limited by reducing the amount of well layers and barrier layers which is advantageous from a manufacturing perspective. The absorption layers 24-26 of materials for absorption of radiation adjoin the respective superlattices forming a pair. They are of such a thickness that the excitation levels are determined by their composition. Suitable values for the thickness are in a range about fifty nm, preferably in a range about ten nm.

The absorption layers 24-26 may comprise a direct semiconductor material. Such a material has a relatively high absorption coefficient of 10⁴ to 10⁶ cm⁻¹ so that the absorption layers 24-26 can be kept thin. For example CdS with a band gap of 2.45 eV has the absorption coefficient at 500 nm around 10⁵ cm⁻¹, Cu(In,Ga) (Se,S)₂, which band gap can be varied in a broad range from 1.0 to 1.7 eV having in this energy range an absorption coefficient between 10⁴ to 10⁵ cm⁻¹. Absorption involves the excitation of electrons from the valence to the conduction band. Relatively high absorption coefficients also characterise an alternative, namely organic molecular materials. Such materials are used in the example described herein. In organic molecular materials, the excited charge carriers are commonly referred to as excitons. Suitable organic molecular materials include porphyrins and phtalocyanines. These have narrow absorption bands around frequencies corresponding to a photon energy level of about 2.9 eV and 1.77 eV, respectively. Phtalocyanine molecules in particular are chemically very stable and can be deposited by vacuum evaporation. The excitation levels of the materials in the absorption layers 24-26 are selected to allow them to match the effective bands of the adjoining superlattices. As the band gaps of these can be engineered through the dimensions of the thin layers 10-21, such matching can be achieved with a relatively high degree of accuracy.

Charge carriers in the absorption layers 24-26 are excited to a level at or above the lower boundary of the effective conduction band of the adjoining superlattice. This allows for transfer of charge carriers to the superlattice with relatively high efficiency. The efficiency is high due to the low thermalisation losses that are incurred when the charge carriers are transferred to the conduction band. Matching is preferably accurate to a value in the range of tenths of an electronvolt, e.g. 0.1 or 0.2 eV. In a molecular material, the charge carriers are excited to the Lowest Unoccupied Molecular Orbital (LUMO), which thus matches the lower boundary of the effective conduction band of the adjoining superlattice. Preferably the state from which the charge carrier is excited—this state is called the Highest Occupied Molecular Orbital (HOMO) in a molecular material for absorbing radiation—matches the effective valence band, at least its upper bound, to the same degree of accuracy.

FIG. 2 illustrates the general concept of the photovoltaic cell 1 by means of an energy diagram. First and second absorbing layers 27,28 adjoin parts of superlattices 29-32. The superlattices 29-32 have substantially the properties of intrinsic semiconducting materials. They form energy selective transport layers, having a conduction or valence band substantially matched to the stable or excitation level of the adjacent absorbing layer 27,28. In fact, as illustrated in FIG. 2, the conduction bands of the superlattices 30, 32 are slightly beneath the excitation levels of the adjacent absorption layers 27, 28, whereas the valence bands of the superlattices 29, 31 are slightly above the stable levels of the adjacent absorbing layers 27, 28.

Parts of a superlattice 30 adjoining the first absorbing layer 27 and of a superlattice 31 adjoining the second absorbing layer 28 form semiconducting regions having different effective band gaps. Whether a part of one of the superlattices 29-32 functions as an effective transport of electrons or holes is determined by the nature of the adjacent semiconducting region of one of three tunnel-recombination junctions 33-35. The tunnel recombination junctions 33-35 each comprise a pair of semiconducting layers, one of which is doped to make it a P-type semiconducting layer, the other to make it an N-type semiconducting layer. The function of the tunnel recombination junctions is to provide a series connection between the respective superlattices 29-32 with integrated absorbing layers 27,28, and to set up an internal electric field within the active region of the photovoltaic cell 1.

FIG. 3 illustrates a variant of the general concept of FIG. 2 of the photovoltaic cell 1 by means of an energy diagram. Again, first and second absorbing layers 27,28 adjoin parts of superlattices 29-32. However, the superlattices 29-32 of a single pair are different in the embodiment of FIG. 3. The superlattices 29-32 are selected to have different effective band gaps within a pair. The band gaps are engineered such that negative charge carriers, excited in the superlattice 29, are forced towards the tunnel-recombination junction 34, whereas positive charge carriers, excited in the superlattice 30, are driven towards the tunnel-recombination junction 33.

FIG. 4 shows a production line 36 for manufacturing an array of solar cells with the configuration of the solar cell 1 that has been described. The production line 36 in the example comprises two stations 37-38, past which a length of foil is advanced. The array of solar cells is formed on the foil as it is transferred from a first roll 39 to a second roll 40. The two stations 37,38 are exemplary only, as there could be more of them. In particular where PEVCD is used, solar cells can be produced very efficiently by forming the layers 10-21, 24-26 in succession at one or more stations 37,38 which are positioned along the foil path. Patterning, using a laser or other cutting technique, is applied to form the individual cells. Due to the use of the first and second rolls 38,39, quasi-continuous production, limited primarily by the maximum practicable diameter of the rolls 39,40, is made possible. Arrays of a suitable size can be formed from the length of foil after further processing, such as the application of plastic protective layers, the removal of a backing layer, etc. The array is then incorporated into a photovoltaic device including suitable connectors and optional additional circuitry. The use of units of spectrum-selective absorbing materials in conjunction with superlattices with effective band gaps engineered to match the absorption bands of the material, especially in a tandem cell configuration, makes the photovoltaic device efficient and relatively uncomplicated to produce.

The invention is not limited to the embodiments described above, which may be varied within the scope of the accompanying claims. For instance, the absorption bands of the materials for absorption of radiation may overlap partially. Also, embodiments are possible wherein one of each pair of semiconducting regions adjoining a layer for spectrum-selective absorption of radiation is made of an inorganic, direct or indirect, semiconducting material, instead of comprising a superlattice. Furthermore, the pairs of semiconducting regions forming a multi-junction cell may be separated by layers of inorganic semiconducting material, or such a layer may be provided in between an electrode and a superlattice.

1. Photovoltaic cell, including at least a first junction between a pair of semiconducting regions, wherein at least one of the pair of semiconducting regions includes at least part of a superlattice comprising a first material interspersed with formations of a second material, which formations are of sufficiently small dimensions so that the effective band gap between effective energy bands of the superlattice is at least partly determined by the dimensions, wherein an absorption layer is provided between the semiconducting regions and wherein the absorption layer comprises a material for absorption of radiation so as to result in excitation of charge carriers and is of such thickness that excitation levels are determined by the material itself, wherein
at least one of the effective energy bands of the superlattice and one of the excitation levels of the material of the absorption layer is selected to match at least one of the excitation levels of the material of the absorption layer and the effective energy band of the superlattice, respectively.

2. Photovoltaic cell according to claim 1, comprising a series of pairs of semiconducting regions, separated by junctions and having effective band gaps decreasing with each pair, wherein at least two of the semiconducting regions include a superlattice and an adjoining layer of a material for absorption of radiation so as to result in excitation of charge carriers, of such thickness that excitation levels are determined by the material itself.

3. Photovoltaic cell according to claim 1, each superlattice comprising a periodically repeating combination of layers of different semiconductor materials, sufficiently thin to provide the superlattice with an effective band gap differing from that of any semiconductor materials in the individual layers of the superlattice.

4. Photovoltaic cell according to claim 1, wherein the superlattice is comprised of intrinsic semiconducting materials and the photovoltaic cell further comprises at least one pair of differently doped N-type and P-type semiconducting regions arranged to give rise to the internal electric field within the photovoltaic cell.

5. Photovoltaic cell according to claim 1, wherein the absorption layer is sandwiched between said semiconducting regions and said semiconducting regions have different effective band gaps.

6. Photovoltaic cell according to claim 1, wherein the material for absorption of radiation comprises at least one of a direct semiconductor, an organic molecular material and a material comprising nano-crystals.

7. Photovoltaic cell according to claim 1, wherein the superlattice comprises a periodically repeating combination of layers of different amorphous semiconductor materials.

8. Photovoltaic cell according to claim 1, wherein the superlattice comprises a periodically repeating combination of layers of hydrogenated semiconductor materials.

9. Method of manufacturing an array of photovoltaic cells, including depositing layers of material on a length of foil and patterning at least some of the layers to form an array of photovoltaic cells, wherein an array of cells according to claim 1 is formed.

10. Method according to claim 9, wherein layers are deposited at least one station in a production line, wherein a quasi-continuous length of foil is advanced past each station.

11. Photovoltaic device including a plurality of photovoltaic cells according to claim 1.
